(19) United States
(12) Patent Application Publication
(10) Pub. No.: US 2025/0192022 A1
(43) Pub. Date: Jun. 12, 2025

(54) PROCESS FOR MANUFACTURING ELECTRONIC COMPONENTS

(71) Applicant: STMicroelectronics International N.V., Geneva (CH)

(72) Inventor: Gregoire DELACOURT, Tours (FR)

(73) Assignee: STMicroelectronics International N.V., Geneva (CH)

(21) Appl. No.: 18/963,176

(22) Filed: Nov. 27, 2024

(30) Foreign Application Priority Data
Dec. 8, 2023 (FR) 2313867

(51) Int. Cl. H01L 23/498; H01L 21/78; H01L 23/00; H01L 23/31

(52) U.S. Cl. CPC H01L 23/49838; H01L 21/78; H01L 23/3178; H01L 23/49883; H01L 23/49894; H01L 24/13; H01L 2224/13023; H01L 2924/14

(57) ABSTRACT

A process is provided for manufacturing electronic components with wettable flanks from a substrate in which chips are formed, the chips being separated by cavities, the process including a first step in which an insulating material layer is deposited and then a second step in which a conductive material layer is deposited on the insulating material layer to form wettable flanks. An electronic component with wettable flanks is also provided.

### BACKGROUND

This application claims the priority benefit of French patent application number 2313867, filed on Dec. 8, 2023, entitled “Procédé de fabrication de composants électroniques,” which is hereby incorporated by reference to the maximum extent allowable by law.

### TECHNICAL FIELD

The present disclosure relates to the manufacture of electronic components, such as the manufacture of so-called surface-mount components or “leadless” components, i.e., they have no visible connections once assembled on the circuit board. These components have on at least one side, one or more connection metallizations designed to be soldered to corresponding connection pads on an external device, such as a printed circuit board or another component.

### BACKGROUND ART

In some applications, there is a need for surface-mounted components in which connection metallizations designed to be soldered to an external device extend right down to the component flanks. These are known as “wettable flank” components. When the component is mounted in its environment (e.g., on a printed circuit board), the connecting metallizations (also known as electrical contacts) are soldered or brazed to corresponding metal tracks or elements on the PCB side. Some of the soldering material then rises to the sides of the components, enabling visual inspection of connection quality.

This need exists, for example, in the automotive or medical fields, and more generally in all areas where it is necessary to ensure the correct assembly of components whose connections are not visible (the connections are under the component) and to guarantee the reliability of electrical connections once the circuits have been installed in their environment.

### BRIEF SUMMARY

There is a need to improve at least some aspects of known processes for manufacturing electronic components with wettable flanks.

This is achieved by a method of manufacturing electronic components with wettable flanks from a substrate in which chips are formed, the chips being separated by cavities, the method can be summarized as including: a first step in which an insulating material layer is deposited in the cavities and a second step in which a conductive material layer is deposited on the insulating material layer to form wettable flanks.

According to an embodiment, the chips can include at least two connection terminals, covered by connection pads and arranged on a first face of the substrate, and wherein, in the first step, the insulating material layer is deposited in the cavities, on the connection pads and on the first face of the substrate.

According to an embodiment, the process can include, prior to the second step, a step in which part of the insulating resin layer present in the cavities is removed, so as to form trenches whose bottom and walls are made of insulating resin, and wherein, in the second step, the conductive material layer is deposited in the trenches.

According to an embodiment, the process further includes the following steps:
Thinning the insulating material layer to make the connection pads accessible; and
Separating the electronic components by cutting the substrate through the conductive material layer.

This is achieved by an electronic component with wettable flanks including a chip protected by a housing whose flanks successively include an insulating material layer and a conductive material layer.

According to an embodiment, the electronic component includes a first main face including at least two connection pads, a second main face and flanks, the conductive material layer being electrically insulated from the connection pads by the insulating material layer, the conductive material layer extending over a portion of the flanks from the first main face.

According to an embodiment, the insulating material layer covers a first face of the chip between the connection pads.

According to an embodiment, the insulating material layer is a layer of an epoxy or phenolic resin in which electrically insulating fillers, for example alumina particles, are dispersed.

According to an embodiment, the conductive material layer is a layer of an epoxy or phenolic resin in which electrically conductive fillers, for example silver, copper or carbon black particles, are dispersed.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings.

FIG. 1 shows a schematic cross-section of an electronic component with wettable flanks according to an embodiment.

FIGS. 2A-2G are cross-sectional views illustrating steps in a process for manufacturing an electronic component with wettable flanks according to an embodiment.

FIGS. 3A-3B are cross-sectional views illustrating steps in a process for assembling an electronic component with wettable flanks with an external device according to an embodiment.

### DETAILED DESCRIPTION

Like features have been designated by like references in the various Figures. The structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and within 5%.

Electronic components are used in a wide range of industrial sectors, such as in the automotive and medical fields.

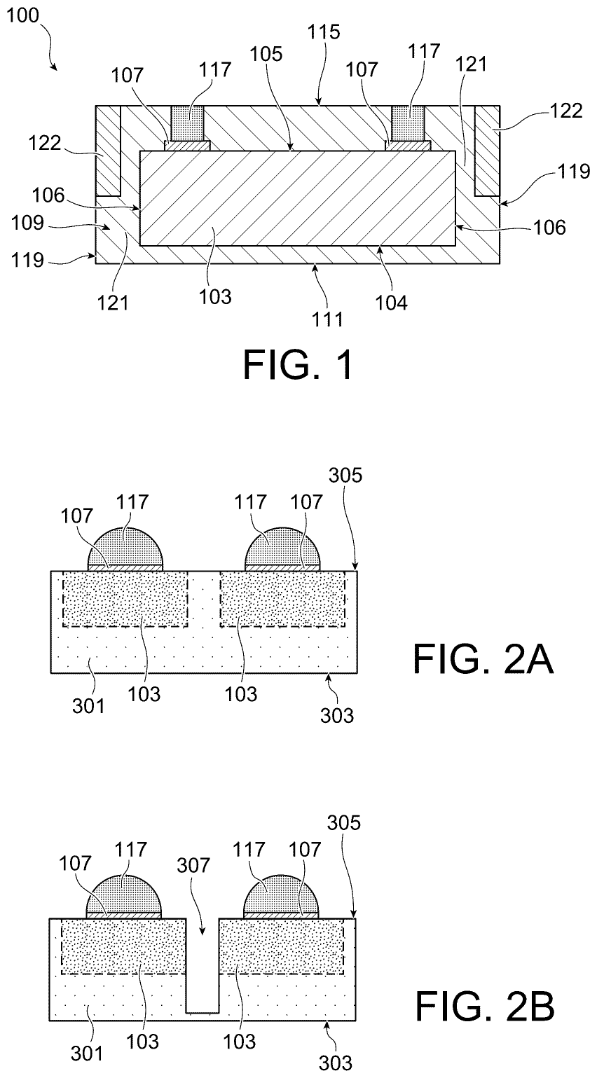

FIG. 1 shows a schematic cross-section of an electronic component 100 with non-through connections.

The electronic component 100 comprises of an electronic chip 103 and a housing 109. In one example, the chip 103 is formed from a semiconductor substrate, such as silicon. It may also be SiC.

The chip 103 comprises a front side 105 (also known as the first side or front face or top face), a rear side 104 (also known as the second side or rear face or bottom face) and sidewalls 106 (also known as side faces). The rear side 104 is opposite to the front side 105.

One or more connection terminals 107 (also known as electrical contacts) are formed on the top surface 105 of the chip 103, enabling it to be connected to other elements (microchips or electronic devices).

The electrical connection terminals 107 are, for example, 10 to 30 μm from the chip 103 side wall 106. The electrical connection terminals 107 can be positioned on the front side 105 of the chip 103 or flush with the top surface (i.e., be at the same level as the top surface 105 of the chip 103).

Electrical connection terminals 107 are also known as “UBMs” (Under Bump Metallization) or «bumping pads». The electrical connection terminals 107 are made of a conductive material specifically designed to receive connection pads 117, and to adhere well to the connection pads 117. Electrical connection terminals 107 comprise at least one of the following elements: gold, titanium, nickel, copper or tungsten. In some embodiments, the electrical connection terminals 107 comprise gold.

The chip 103 can comprise one or more discrete components. The discrete component or components are, for example, selected from transistors, diodes, thyristors, triacs, filters, etc. Chip 103 can comprise one or more electronic circuits. The chip 103 can be used to implement various electronic functions.

Component 100 is an integrated component.

The chip 103 is protected by the housing 109. The housing 109 covers at least the top surface 105 and the sides 106 of the chip 103. According to a variant not shown, the housing 109 may also cover the rear side 106 of the chip 103.

The housing 109 is made of an electrically insulating material.

In order to connect the component 100 to other electronic components and/or circuits, the housing 109 also includes connection pads 117 (also known as housing contacts or contact covers). The connection pads 117 are positioned on the top surface 105 of the chip 103. Each pad 117 is connected to the connection terminal 107 on the chip 103.

The connection pads 117 are made of an electrically conductive and “wettable” material (i.e., solderable), i.e., a material that can be soldered.

The electrical connection terminals 107 of the chip 103 and contact connection pads 117 are positioned in openings of a layer of insulating material 121 covering the chip 103. In one embodiment, the layer of insulating material 121 is an insulating resin layer.

The component 100 is a wettable flange component, i.e., at least part of the flanks 119 of the housing 109 is covered by a layer of a conductive material 122 made of a wettable material, i.e., a material on which it is possible to solder.

The conductive layer 122 partially covers sides 119 of the housing 109 from the top.

In some embodiments, the conductive layer 122 is a conductive resin layer.

The conductive layer 122 partially covers the insulating material layer 121. It is electrically insulated from the connection pads 117 by the insulating material layer 121.

The wettable flank device makes it easy to see whether the component 100 has been properly soldered to another device.

We will now describe the manufacturing process for electronic components with wettable flanks. This process comprises a step in which a layer of insulating material 121 is deposited on the sidewalls 119 of the electronic components 100, followed by a step in which a layer of conductive material 122 is deposited on the insulating material layer 121.

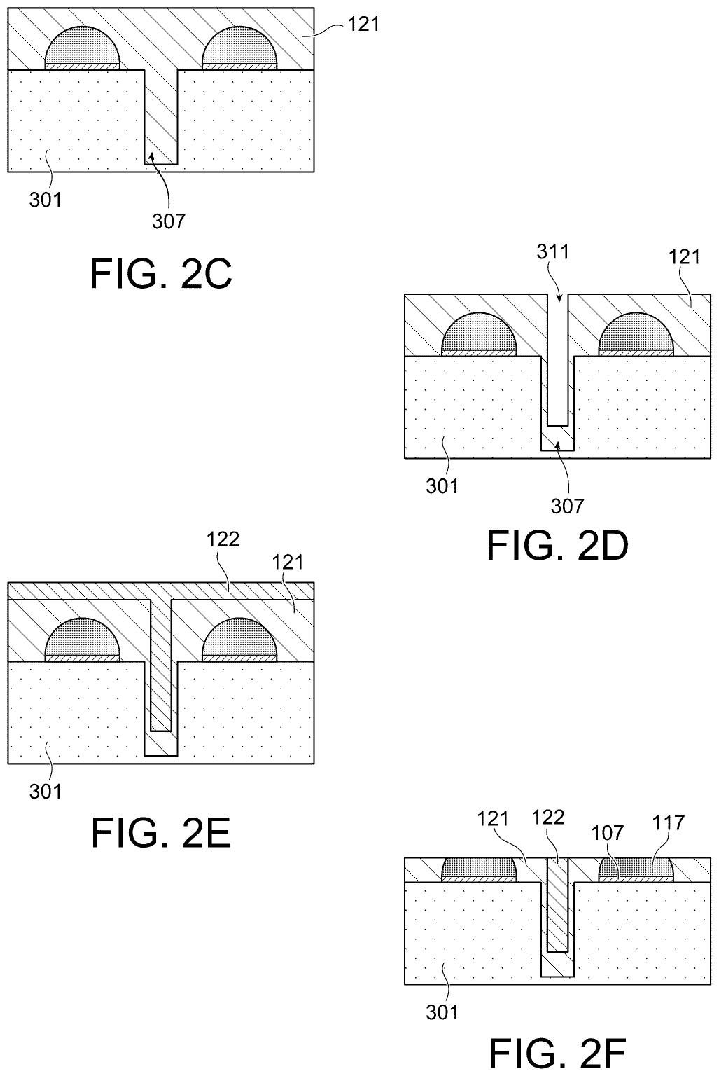

The process comprises the following steps:
a) Provide a substrate 301 in which chips 103 are formed, the chips 103 including at least two connection terminals 107, covered by connection pads 117, and arranged on a first main face 305 of the substrate 301 (FIG. 2A);
b) Partially cut the substrate 301 between the chips 103 to form cavities 307, the walls of the cavities 307 corresponding to the side walls of the chips 103 (FIG. 2B);
c) Apply a layer of insulating material 121, whereby the insulating material 121 covers the metal connection pads 117, covers the first side 305 of the substrate 301 between the connection terminals 107 and fills the cavities 307 (FIG. 2C);
d) Remove some of the insulating material from the cavities 307 to form trenches 311 (FIG. 2D);
e) Apply a layer of conductive material 122 to the layer of insulating material 121, the conductive material filling the trenches 311 (FIG. 2E);
f) Thin the device to make the connection pads 117 accessible (FIG. 2F); g) Separate the components 100 by cutting the substrate 301 through the conductive material, thus obtaining components 100 with wettable flanks (FIG. 2G).

In step a), manufacture of the discrete component(s) and/or integrated circuit(s) forming the components 100 is complete. The components 100 are formed from a single substrate 301, and have not yet been individualized. The chips 103 are delimited by a dotted line in the substrate 301 on the Figures. The substrate 301 has a first face 305 (top or front face) and a second face 303 (back or bottom face).

The substrate 301 is, for example, a semiconductor substrate, such as silicon.

The substrate 301 has a thickness of between 300 and 900 μm, for example, a thickness of around 725 μm.

In addition, electrical connection terminals 107, described in relation to FIG. 1, have been formed on an upper face 305 of the substrate 301 (FIG. 2A).

The electrical connection terminals 107 are covered by metallic connection pads 117, such as in the shape of a “bump”. Alternatively, it can be a conductive element in another shape, such as a pillar or cube.

The metal connection pads 117 enable direct contact to be made with the front 115 of the housing 119.

Advantageously, the metal connection pads 117 are soldered to the electrical connection terminals 107. For example, the metal pads are made of a solderable tin-based material, such as SnAgCu.

In the Figures, the chips 103 are shown with similar dimensions. Alternatively, they may have different dimensions. An electrical connection terminal 107 is shown for better legibility, but each chip 103 comprises at least two connection terminals 107. The person skilled in the art will know how to adapt the manufacturing process described here in this case.

In step b), a step of cutting partially the components 100 is performed, for example by a mechanical cutting process such as blade sawing. Cavities 307 defining the lateral contours of the chips 103 of the components 100 are formed in the substrate 301. The cavities 307 extend from the top face 305 of the substrate 301. According to one example, a depth of the cavities 307 corresponds to a desired thickness of the chips of the components 100. According to one example, the depth of the cavities 307 is of the order of 100 or 300 μm. The depth can be modified to suit the application.

The cavities 307 formed in step b) are between 50 and 80 μm thick and 100 to 150 μm deep. The thickness can be modified to suit the application.

This step b) is carried out using a cutting device. The cutting device is, for example, a mechanical engraving tool such as a blade saw, or a laser engraving tool.

In step c), the walls of the cavities 307 are covered with insulating material. To achieve this, a layer 121 of insulating material is deposited in the cavities 307, on the first side 305 of the substrate 301 and on the connection pads 117. In this way, the connection pads 117 are arranged within the insulating material. The insulating material layer 121 forms a first part of the casing 109 of the components 100. This first part of the casing protects the top face of the components 100, and at least part of the sides of the components 100.

In step c), the insulating material can be deposited using a press or by vacuum molding.

The insulating material may comprise an electrically insulating resin. It may be a thermosetting resin or a thermoplastic resin. The material will be chosen so as not to be fusible over the operating temperature range of the electronic components. The resin can be chosen from the group comprising: epoxy-type resins, phenolic-type resins, acrylic-type resins.

The insulating material may also include electrically insulating particles. The particles are, for example, oxide particles, in particular alumina or silica particles.

Polymerization is, for example, a UV polymerization step or thermal activation polymerization.

Annealing can be carried out before step d).

In step d), a cutting step is carried out to form trenches 311 in the layer of insulating material 121. The trenches 311 are formed in the cavities 307. A portion of the insulating material remains in the cavities. This part covers the bottom and side walls of the cavities 307. In one example, the thickness of insulating material remaining on the side walls of cavities 307 is between 5 and 20 μm, for example between 5 and 10 μm. The bottom of the cavities 307 can be covered by a thickness of 1 to 10 μm of insulating material.

The trenches 311 are created using a cutting device. The cutting device is, for example, a mechanical engraving tool such as a saw, or a laser engraving tool. In one embodiment, the cutting device is a laser.

In step e), a conductive material layer 122 is deposited on the insulating material layer 121. The conductive material layer 122 is deposited at least in the trenches 311 so as to cover the insulating material layer 121. It can be a full-plate deposition.

The conductive material is an electrically conductive resin. The resin layer 121 comprises at least one base material to which metal particles coated with an electrically insulating protective layer are added.

The base material ensures the adhesion of the layer 122 to the material 121 and the particles ensure the final wettability of the layer 122.

The base material is selected from the group comprising: epoxy-type resins, phenolic-type resins, acrylic-type resins. The metal particles are, for example, metal particles whose material is selected from the group comprising: copper, an alloy comprising copper, titanium, an alloy comprising titanium, nickel, an alloy comprising nickel, silver, and an alloy comprising silver.

According to an embodiment, the conductive resin layer 122 can be deposited by screen printing or by vacuum molding.

Polymerization is, for example, a UV polymerization step or by thermal activation.

Annealing can be carried out after step e) and before step f).

The process includes a step f) of thinning the front panel to make the conductive pads 117 accessible. The contacts of the housing 109 of the components 100 are then completely formed. The front panel thinning step can be carried out by grinding.

The process can also include a step of thinning the substrate 301 on the rear face 303. To do this, the structure is turned over and fixed by its front face, i.e., face 305. The support is, for example, a strip of adhesive tape. The structure is then thinned by its rear face 303 so that the substrate 301 has its final thickness. In one example, the structure 301 is thinned down to the cavities 307.

The process can advantageously include a step between step f) and step g), during which an additional insulating layer is deposited on the rear face 303 of the structure to form the rear face 111 of the housing 109. In this way, all sides of substrate 301 are protected by either layer 121 or the additional insulating layer.

The additional insulating layer is made of an electrically insulating material, e.g., a resin of the same type as the resin in layer 121. In another example, the layer materials are different.

In step g), the components are individualized by cutting through the conductive resin 122. The components 100 are thus separated from one another.

The metallic particles of the conductive material 122 are then exposed, ensuring the wettability function of the flanks 119 of the electronic components 100.

The resulting components 100 are surface-mounting devices (SMDs) of the “flip-chip” type, i.e., they can be fixed to a support, such as a printed circuit board, by their top face, i.e., the face on which the contacts 117 of the housing 109 are arranged.

The components could also be DFN (“dual flat no-lead”) or QFN (“quad flat no-lead”) components. These components have no lead connections. These do not protrude beyond the resin body of the package.

Such components are interesting for guaranteeing the reliability of electrical connections, once the circuits have been mounted in their environment.

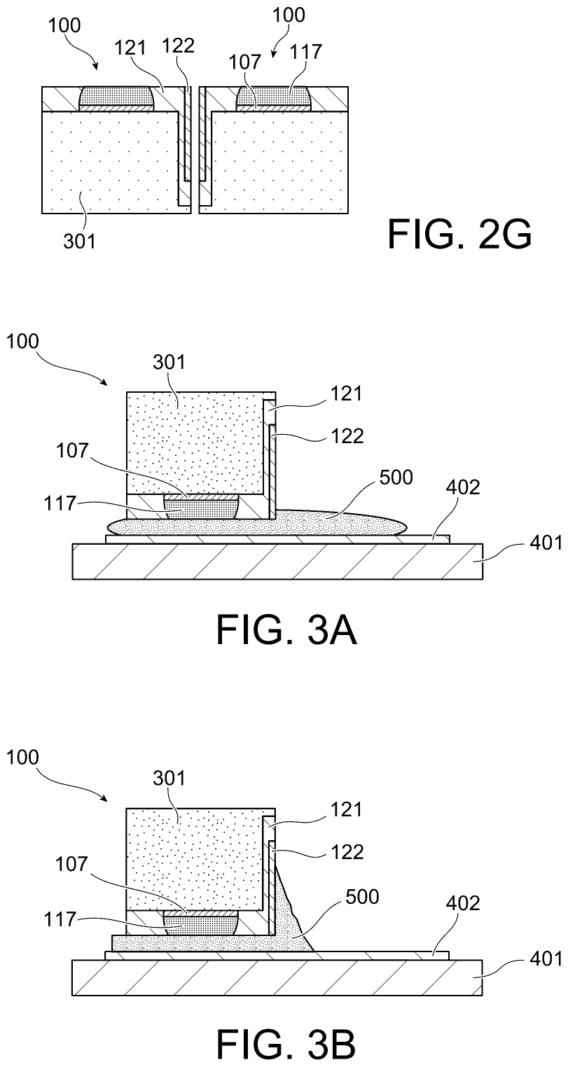

FIGS. 3A and 3B show steps in a process for assembling a component 100 on an external device, such as a printed circuit board or other component.

The external device comprises a substrate 401 covered by tracks 402.

A brazing material 500 is positioned between the component 100 and the tracks 402 external device 400 (FIG. 3A). During soldering, soldering material 500 rises up to the wettable flanks 122 of the components, allowing verification that soldering has been carried out correctly.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

A method of manufacturing electronic components (100) with wettable flanks from a substrate (301) in which chips (103) are formed, the chips (103) being separated by cavities (307), the method is summarized as including a first step in which an insulating material layer (121) is deposited in the cavities and a second step in which a conductive material layer (122) is deposited on the insulating material layer (121) to form wettable flanks.

The chips (103) includes at least two connection terminals (107), covered by connection pads (117) and arranged on a first face (305) of the substrate (301), and, in the first step, the insulating material layer (121) may be deposited in the cavities (307), on the connection pads (117) and on the first face (305) of the substrate (301).

The process includes, prior to the second step, a step in which part of the insulating resin layer present in the cavities (307) is removed, so as to form trenches (311) whose bottom and walls are made of insulating resin, and, in the second step, the conductive material layer (122) may be deposited in the trenches (311).

The process further includes the following steps: thinning the insulating material layer (121) to make the connection pads (117) accessible, separating the electronic components (100) by cutting the substrate (301) through the conductive material layer (122).

Electronic component (100) with wettable flanks is summarized as including a chip (103) protected by a housing (109) whose flanks successively comprise an insulating material layer (121) and a conductive material layer (122).

The electronic component includes a first main face (115) including at least two connection pads (117), a second main face (111) and flanks (119), the conductive material layer (122) being electrically insulated from the connection pads (117) by the insulating material layer (121), the conductive material layer (122) extending over a portion of the flanks (119) from the first main face (115).

The insulating material layer (121) cover a first face (105) of the chip (103) between the connection pads (117).

The insulating material layer (121) is a layer of an epoxy or phenolic resin in which electrically insulating fillers, for example alumina particles, are dispersed.

The conductive material layer (122) is a layer of an epoxy or phenolic resin in which electrically conductive fillers, for example silver, copper or carbon black particles, are dispersed.

A method of manufacture for a component can be summarized as including: arranging a substrate with chips formed on the substrate, wherein the chips include at least two connection terminals covered by connection pads; partially cutting the substrate between the chips to form cavities; applying a layer of insulating material that covers the connection pads and substrate, wherein the insulating layer fills the cavities; removing the portions of the layer of insulating material from the cavities to form trenches; and applying a layer of conductive material to the layer of insulating material, the layer of conductive material filling the trenches.

The chips can include a first side, a second side opposite the first side, and sidewalls transverse to the first and second sides. At least two connection terminals can be formed on the first side of the chips. The method can include thinning the component to make the connection pads accessible; and separating the components by cutting the substrate through the layer of conductive material to obtain components with wettable flanks.

The substrate can include a first face and a second face opposite the first face, the substrate having a thickness between 300 and 900 μm. The substrate can be a semiconductor substrate. Partially cutting the components can be carried out by a mechanical cutting process. The cavities can define lateral contours of the chips of the components formed in the substrate, the cavities extending from the first face of the substrate. A depth of the cavities corresponds to a thickness of the chips of the components. A depth of the cavities can be 100 or 300 μm. The cavities can be between 50 and 80 μm thick and 100 to 150 μm deep. The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
depositing an insulating material layer in cavities; and
forming wettable flanks by depositing a conductive material layer on the insulating material layer.

2. The method according to claim 1, further comprising a substrate, wherein chips comprise at least two connection terminals covered by connection pads and arranged on a first face of the substrate, and wherein the insulating material layer is deposited on the connection pads, and on the first face of the substrate.

3. The method according to claim 2, wherein the process further comprises, prior to forming wettable flanks, removing a portion of an insulating resin layer present in the cavities forming trenches having a bottom surface and sidewalls made of insulating resin, and wherein the conductive material layer is deposited in the trenches.

4. The method according to claim 2, further comprising:
thinning the insulating material layer making the connection pads accessible, and
separating electronic components by cutting the substrate through the conductive material layer.

5. A device, comprising:
a chip protected by a housing, wherein the housing comprises flanks;
an insulating material layer; and
a conductive material layer.

6. The device according to claim 5, further comprising:
a first main face having at least two connection pads;
a second main face opposite the first main face; and
flanks, the conductive material layer being electrically insulated from the connection pads by the insulating material layer, the conductive material layer extending over a portion of the flanks from the first main face.

7. The device according to claim 5, wherein the insulating material layer covers a first face of the chip between the connection pads.

8. The device according to claim 5, wherein the insulating material layer is a layer of an epoxy or phenolic resin wherein electrically insulating fillers, are dispersed.

9. The device according to claim 5, wherein the conductive material layer is a layer of an epoxy or phenolic resin wherein silver, copper or carbon black particles, are dispersed.

10. A method, comprising:
arranging a substrate with chips formed on the substrate, wherein the chips include at least two connection terminals covered by connection pads;
cutting the substrate between the chips to form cavities;
applying a layer of insulating material that covers the connection pads and substrate, wherein the insulating layer fills the cavities;
removing portions of the layer of insulating material from the cavities to form trenches; and
applying a layer of conductive material on the layer of insulating material, the layer of conductive material filling the trenches.

11. The method of claim 10, wherein the chips include a first side, a second side opposite the first side, and sidewalls transverse to the first and second sides.

12. The method of claim 11, wherein the at least two connection terminals are formed on the first side of the chips.

13. The method of claim 10, further comprising:
thinning the component to make the connection pads accessible; and
separating the components by cutting the substrate through the layer of conductive material to obtain components with wettable flanks.

14. The method of claim 10, wherein the substrate has a first face and a second face opposite the first face, the substrate having a thickness between 300 and 900 μm.

15. The method of claim 10, wherein the substrate is a semiconductor substrate.

16. The method of claim 10, wherein partially cutting the components is carried out by a mechanical cutting process.

17. The method of claim 14, wherein the cavities define lateral contours of the chips of the components formed in the substrate, the cavities extending from the first face of the substrate.

18. The method of claim 10, wherein a depth of the cavities corresponds to a thickness of the chips of the components.

19. The method of claim 10, wherein a depth of the cavities is 100 or 300 μm.

20. The method of claim 10, wherein the cavities are between 50 and 80 μm thick and 100 to 150 μm deep.
